(19) United States
(12) Patent Application Publication
(10) Pub. No.: US 2025/0294929 A1
(43) Pub. Date: Sep. 18, 2025

(54) Laminate Passivation for Micro LED

(71) Applicant: Apple Inc., Cupertino, CA (US)

(72) Inventors: Benjamin P. Yonkee, Castro Valley, CA (US); Fang Ou, San Jose, CA (US); Tso Chi Chang, Sunnyvale, CA (US); Eric P. Young, Cupertino, CA (US); Clayton K. Chan, Fremont, CA (US); Vijay P. Rawat, Palo Alto, CA (US)

(21) Appl. No.: 19/040,377

(22) Filed: Jan. 29, 2025

Related U.S. Application Data
(60) Provisional application No. 63/566,569, filed on Mar. 18, 2024.

(51) Int. Cl. H10H 20/841; H10H 20/853

(52) U.S. Cl. CPC H10H 20/841; H10H 20/853

(57) ABSTRACT

Micro LED structures and electronic devices are described in which the micro LED structures are provided with a multi-layer encapsulation layer to mitigate passivation defects that can exist and address reliability and process integration requirements.

### RELATED APPLICATIONS

This application claims the benefit of priority of U.S. Provisional Application No. 63/566,569, filed Mar. 18, 2024, which is incorporated herein by reference.

### BACKGROUND

### Field

Embodiments described herein relate to light emitting diodes (LEDs). More particularly embodiments relate to LED sidewall passivation layers.

### Background Information

Inorganic semiconductor-based light emitting diodes (LED) may typically be fabricated from III-V or II-VI systems such as GaN/InGaN and InGaAlP systems. Generally, a vertical inorganic semiconductor-based micro LED may include a p-doped cladding layer for hole injection, an n-doped cladding layer for electron injection, and an active layer therebetween. The active layer may include one or more quantum well layers and barrier layers for example. In operation light is emitted as a result of recombination of holes and electrons in the quantum wells.

More recently it has been proposed to integrate arrays of vertical micro LEDs into display and lighting assemblies, with maximum widths of the vertical micro LEDs scaled down to as much as 1 μm.

### SUMMARY

Micro LED structures, electronic structures with integrated micro LED structures and methods of fabrication are described. In an embodiment a micro LED structure includes a micro diode including a top cladding layer with a first dopant type (e.g., n-type) and a bottom cladding layer with a second dopant type (e.g., p-type) opposite the first dopant type. A sidewall passivation layer spans around sidewalls of the micro diode and at least partially underneath the micro diode, and forms an outline around the micro diode. A multi-layer encapsulation layer is additionally formed on the sidewall passivation layer, and forms an outline along a portion of the sidewall passivation layer.

### BRIEF DESCRIPTION OF THE DRAWINGS

FIG. 1 is a cross-sectional side view illustration of a micro LED including a multi-layer encapsulation layer in accordance with an embodiment.

FIG. 2 is a schematic cross-sectional view of a multi-layer encapsulation layer in accordance with an embodiment.

FIG. 3 is a cross-sectional side view illustration of a micro LED including a multi-layer encapsulation layer in accordance with an embodiment.

FIG. 4 is a schematic cross-sectional side view illustration of a micro LED bonded on a display substrate in accordance with an embodiment.

FIG. 5 is an isometric view of a mobile telephone in accordance with an embodiment.

FIG. 6 is an isometric view of a tablet computing device in accordance with an embodiment.

FIG. 7 is an isometric view of a wearable device in accordance with an embodiment.

FIG. 8 is an isometric view of a laptop computer in accordance with an embodiment.

FIG. 9 is a system diagram of a portable electronic device in accordance with an embodiment.

### DETAILED DESCRIPTION

Embodiments describe micro LED structures, displays including micro LED structures and methods of manufacture in which a multi-layer encapsulation is provided around each micro LED.

In one aspect, it has been observed that micro LEDs are subject to more stringent reliability requirements than large area or mini-LEDs due to low failure rate required and high surface to volume ratio. Small passivation defects that exist can lead to complete device failure in environmental reliability conditions due to metal migration or semiconductor degradation. In accordance with embodiments, a multi-layer encapsulation is incorporated in order to address reliability requirements and meet other process integration requirements.

The micro LED encapsulation can include a multi-layer stack with the various layers providing different functions, such as compatibility with the micro LED materials, chemical resistance, hermiticity, roughness evolution, defect propagation, physical modulus, refractive index, adhesion etc. where repeating the film layers can provide better properties than either film alone.

The total stack can also maximize micro LED efficiency or control Lambertianality. This could be done by tuning the thicknesses of the layers for optical interference similar to a distributed Bragg reflector (DBR) structure.

As used herein, the terms “micro” LED or structure are meant to refer to the scale of 0.1 to 300 μm. In an embodiment, a single micro LED or structure has a maximum dimension, for example length or width, of 0.1 to 300 μm, or 0.1 to 100 μm. In an embodiment, the top contact surface of each micro LED has a maximum dimension of 0.1 to 300 μm, 0.1 to 100 μm, or more specifically 0.1 to 20 μm, or 0.1 to 10 μm. More specifically, in some embodiments, “micro” LEDs may be on the scale of 0.1 μm to 20 μm, such as 10 μm, 5 μm, 3 μm, or 1 μm where the LED lateral dimensions approach or surpass the carrier diffusion length. However, it is to be appreciated that embodiments are not necessarily so limited, and that certain aspects of the embodiments may be applicable to larger, and possibly smaller size scales.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “above”, “over”, “to”, “between”, “spanning” and “on” as used herein may refer to a relative position of one layer with respect to other layers. One layer “above”, “over”, “spanning” or “on” another layer or bonded “to” or in “contact” with another layer may be directly in contact with the other layer or may have one or more intervening layers. One layer “between” layers may be directly in contact with the layers or may have one or more intervening layers.

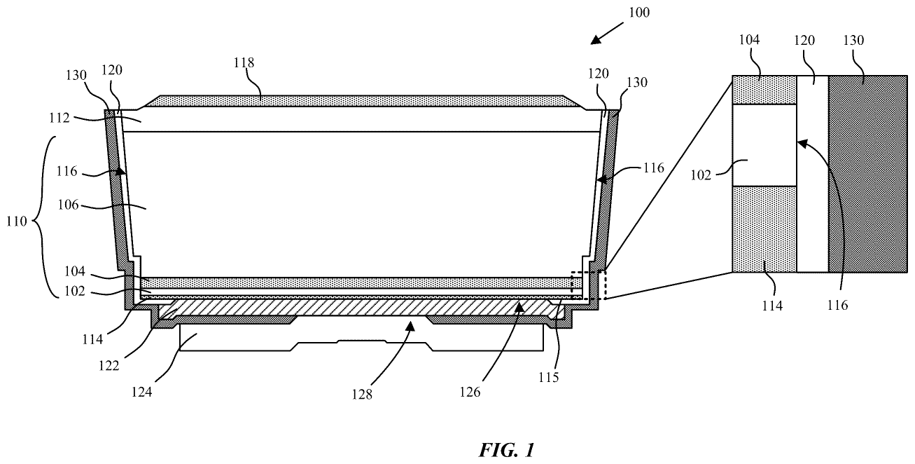

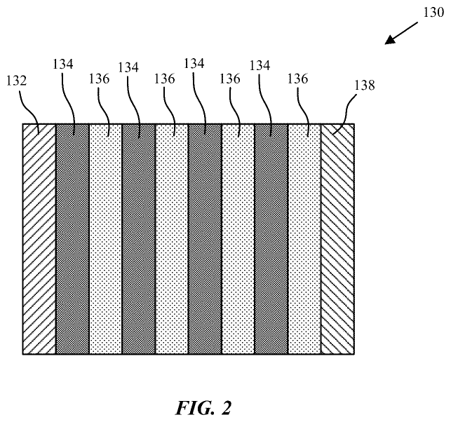

Referring now to FIGS. 1-2, FIG. 1 is a cross-sectional side view illustration of a micro LED including a multi-layer encapsulation layer in accordance with an embodiment; FIG. 2 is a schematic cross-sectional view of a multi-layer encapsulation layer in accordance with an embodiment. As shown in FIG. 1, the micro LED 100 can include a micro diode 110 including at least a top cladding layer 106 with a first dopant type (e.g., n-type) and a bottom cladding layer 102 with a second dopant type (e.g., p-type) that is opposite the first dopant type. The micro diode 110 may further include an active layer 104 between the top cladding layer 106 and the bottom cladding layer 102. The active layer 104 may be a single layer, or multiple layers. For example, the active layer may include one or more layers of alternative quantum well layer(s) and barrier layers.

The micro diodes 110 in accordance with embodiments may be designed for emission of primary red light (e.g. 620-750 nm wavelength), primary green light (e.g. 495-570 nm wavelength), or primary blue light (e.g. 450-495 nm wavelength), though embodiments are not limited to these exemplary emission spectra. The micro diodes 110 may be formed of a variety of compound semiconductors having a bandgap corresponding to a specific peak emission wavelength in the spectrum. For example, the micro diodes 110 can include one or more layers based on II-VI materials (e.g. ZnSc) or III-V materials including III-V nitride materials (e.g. GaN, AlN, InN, InGaN, and their alloys), III-V phosphide materials (e.g. GaP, AlGaInP, and their alloys), and III-V arsenide alloys (AlGaAs).

In an exemplary embodiment the micro diode 110 and micro LED 100 of FIG. 1 is designed for blue or green emission, the bottom cladding layer 102 is formed of p-doped GaN, the top cladding layer is formed of n-doped GaN, and the active layer 104 is formed of one or more layers of AlGaN, InGaN, AlN, InAlN, or AlInGaN. It is to be appreciated that these lists of materials are exemplary and embodiments are not limited to these specific materials and combinations of materials. Furthermore, doping of cladding layers can be reversed.

In an exemplary embodiment the micro diode 110 and micro LED 100 of FIG. 1 is designed for red emission, the bottom cladding layer 102 is formed of p-doped AlInP, AlGaInP, or AlGaAs, and top cladding layer 102 is formed of n-doped GaAs, with the active layer 104 formed of one or more layers of AlGaInP, AlGaAs, or InGaP. It is to be appreciated that these lists of materials are exemplary and embodiments are not limited to these specific materials and combinations of materials. Furthermore, doping of cladding layers can be reversed.

It to be appreciated that the micro diodes 110 illustrated in FIG. 1 are simplified and may include additional layers within the same semiconductor systems, including various spacer layers, buffer layers, blocking layers, signal layers, etc. without varying from the scope of the embodiments described herein. Still referring to FIG. 1, a top contact layer 112, such as a highly doped n-GaN layer for a nitride-based system can be formed on top of the micro diode 110. A transparent top contact layer 118 can be formed over the top contact layer 112. For example, the transparent top contact layer 118 can be a transparent conductive oxide (TCO) material, such as indium tin oxide (ITO). Furthermore, a bottom contact layer 114, such as a TCO material (e.g., ITO) can be formed underneath the micro diode 110.

Still referring to FIG. 1, the micro LED 100 in accordance with embodiments can further include a sidewall passivation layer 120 spanning around sidewalls 116 of the micro diode 110 and at least partially underneath the micro diode 110. As shown, the sidewall passivation layer 120 may form an outline around the micro diode 110 and be formed directly on an underside 115 of the bottom contact layer 114. The sidewall passivation layer 120 in accordance with embodiments can be formed of suitable materials that are compatible with the micro diode 110, bottom contact layer 114, as well as additional layers such as a mirror layer 122 or bonding layer 124 that will be described in further detail. Furthermore, the sidewall passivation layer 120 may be formed of a material an in manner to satisfy dangling bonds or surface defects along the sidewalls 116 in order to reduce potential sites for non-radiative recombination. The sidewall passivation layer 120 can be formed of materials such as re-grown semiconductor materials used in the LED systems as described above, or from metal oxide materials. For example, aluminum oxide can be grown using a high-quality, and conformal, thin film technique such as atomic layer deposition (ALD) to form a low-defect layer, and layer which satisfies available surface states of the material(s) onto which it is formed. In an embodiment, the sidewall passivation layer 120 is 0-1,000 nm thick, such as 1-100 nm thick, and may have a uniform thickness that conforms to the underlying substrate topography and forms an outline.

The sidewall passivation layer 120 may then be patterned to form an opening 126 that exposes the bottom contact layer 114. For example, this may be accomplished using a fluorine based dry etching technique. A mirror layer 122 can then be formed spanning a portion of the sidewall passivation layer 120 and in direct contact with the bottom contact layer 114 within the first opening 126 in the sidewall passivation layer. For example, the mirror layer 122 may be formed of a suitable material, such as silver or aluminum, depending upon the peak emission wavelength of the micro LED 100.

Still referring to FIG. 1, a multi-layer encapsulation layer 130 can then be formed that forms an outline along at least a portion of the sidewall passivation layer 120. For example, where the mirror layer 122 already overlaps a portion of the sidewall passivation layer 120 the multi-layer encapsulation layer 130 may then also form an outline along and underneath a portion of the mirror layer 122. Thus, the outline may be continuous across multiple materials, and may have a uniform thickness that conforms to the underlying topography to form the outline.

The multi-layer encapsulation layer 130 can then be patterned to form an opening 128 that exposes the mirror layer 122. This may be accomplished using a suitable technique depending upon the materials of the multi-layer encapsulation layer 130. A bonding layer 124 can then be formed spanning a portion of the multi-layer encapsulation layer 130 and in direct contact with the mirror layer 122 within the second opening 128 in the multi-layer encapsulation layer 130. For example, the bonding layer 124 may be formed of a suitable material, such as gold, that may readily diffuse with a lower melting temperature bonding layer such as a solder material used for bonding the micro LED 100 to another substrate, such as a display substrate within an electronic device.

Referring now to FIG. 2, an exemplary illustration is provided for a multi-layer encapsulation layer 130 in accordance with embodiments. In accordance with embodiments the multi-layer encapsulation layer 130 may protect the micro LED 100, including the micro diode 110 and other layers from the environment, including surrounding layers and process conditions during product integration as well as ambient. The sidewall passivation layer 120 on the other hand may provide device performance by passivating the micro diode 110 sidewalls 116 and reducing potential defect sites. In an embodiment, the multi-layer encapsulation can optionally include a first adhesion layer 132 that is formed directly on the sidewall passivation layer 120 (as well as any other exposed layer, such as mirror layer 122), and one or more barrier layer(s) 134, 136. The initial, and optional, adhesion layer 132 can be used for compatibility with the micro LED 100 materials, such as those used for mirror layer (e.g., silver and aluminum), the semiconductor materials used for the micro diode 110 system, and bottom contact layer 114 materials (e.g., TCOs such as ITO). While not required, the first adhesion layer 132 can be formed of the same composition as the sidewall passivation layer 120 (e.g., aluminum oxide). The next section of the stack can include one or more barrier layer(s) 134, 136 chosen for various properties such as chemical resistance, hermiticity, roughness evolution, defect propagation, physical modulus, refractive index etc. Exemplary materials can include at least zirconium oxide, tantalum oxide, hafnium oxide, and aluminum oxide. Some metal oxide materials selected for purpose however have been found to interact with materials used for the bottom contact layer 114 materials.

Hafnium oxide for example, may provide such properties, though has been observed to interact with ITO. As such, a barrier layer including hafnium oxide may be separated from the bottom electrode layer by one or more layers including another barrier layer, adhesion layer 132, and/or sidewall passivation layer 120, and combinations thereof. As shown in FIG. 1, the multi-layer encapsulation layer 130 may not make direct contact with the bottom contact layer 114.

In accordance with embodiments, a plurality of barrier layers includes alternating layers of a first group of barrier layers 134 of a first metal oxide composition and a second group of barrier layers 136 of a second metal oxide composition different from the first metal oxide composition. In this aspect, it has been observed that alternating the barrier layers provides better properties than either barrier layer alone. These can be alternated until the environmental reliability requirements are met. In an embodiment, the multi-layer encapsulation layer 130 includes a hafnium oxide layer, a zirconium oxide layer, a tantalum oxide layer, or an aluminum oxide layer. In an embodiment, the multi-layer encapsulation layer 130 includes a plurality hafnium oxide layers, a plurality of zirconium oxide layers, a plurality of tantalum oxide layers, a plurality of aluminum oxide layers, or combinations thereof. For example, the first group of barrier layers and the second group of barrier layers can include any combination of alternating layers of metal oxides with different compositions. A final optional adhesion layer 138 can be optionally added for process integration requirements such as adhesion or subsequent process compatibility. In an exemplary embodiment the final optional adhesion layer 138 is aluminum oxide.

The total stack of the multi-layer encapsulation layer 130 can also be chosen to maximize micro LED efficiency or control Lambertianality. This could be done by tuning the thicknesses of the layers for optical interference similar to a distributed Bragg reflector (DBR) structure. As such, where the micro diode 110 is DBR structure designed to be reflective of the peak wavelength range. In such as configuration, each alternating dielectric layer 134, 136 may have a thickness of approximately one quarter of the peak emission wavelength of the micro diode 110.

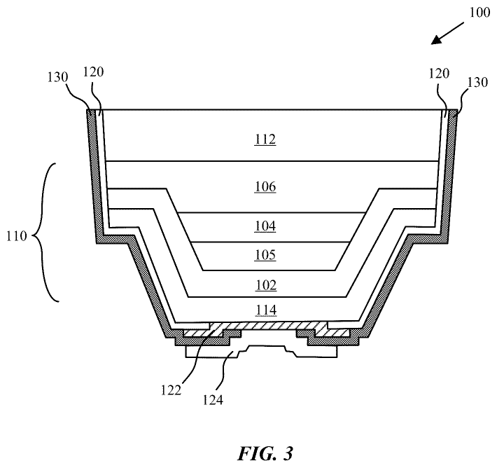

It is to be appreciated that the micro LED 100 structure and micro diode 110 arrangement illustrated in FIG. 1 is exemplary, and the multi-layer encapsulation layer 130 in accordance with embodiments can be integrated into a variety of micro LED 100 structures. FIG. 3 is a micro LED 100 structure bearing many similarities to that of FIG. 1, with one difference being the inclusion of a regrown bottom cladding layer 102. As shown, a mesa structure can be etched though the active layer 104 and an optional spacer layer 105 and into the upper cladding layer 106. The spacer layer 105 may be formed of the same material and stoichiometric composition as the bottom cladding layer (e.g. p-type cladding layer) to be subsequently formed. This can facilitate crystal quality for regrowth, though this is not strictly required. The spacer layer 105 may provide various functions, including providing a surface for regrowth, moving the regrowth interface a minimum distance away from the active layer 104, as well as to provide a diffusion barrier for p-dopants to the active layer 104. In an embodiment, the spacer layer 105 is unintentionally doped. This can be followed by regrowth of the bottom cladding layer 102 over the etched surface. Such a configuration may further passivation the sidewalls of the active layer 104. Layer formation can otherwise be substantially similar to that of FIG. 1, including formation of the sidewall passivation layer 120 and multi-layer encapsulation layer 130.

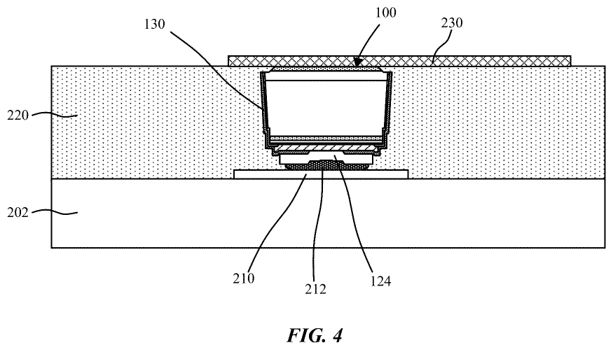

FIG. 4 is a schematic cross-sectional side view illustration of a micro LED 100 mounted on a display substrate 202 in accordance with an embodiment. As shown, a bonding pad 210 can be formed on the display substrate 202. For example, the bonding pad 210 may be connected to driving circuitry within the display substrate 202. The micro LED 100 may be bonded to the bonding pad 210 with a bonding material 212 such as a solder material that bonds the bonding layer 124 to the bonding pad 210. The micro LED 100, and for that matter a plurality or array of micro LEDs, can be encapsulated within a layer of an insulation fill material 220, such as a polymer material. The insulation fill material may additionally function to hold the micro LED in place and provide step coverage for the formation of a top electrode layer 230, such as a transparent conductive oxide (TCO) or transparent polymer material to provide electrical connection to the top side of the micro LED 100. The top electrode layer 230 may be formed directly on the top contact layer 112, for example.

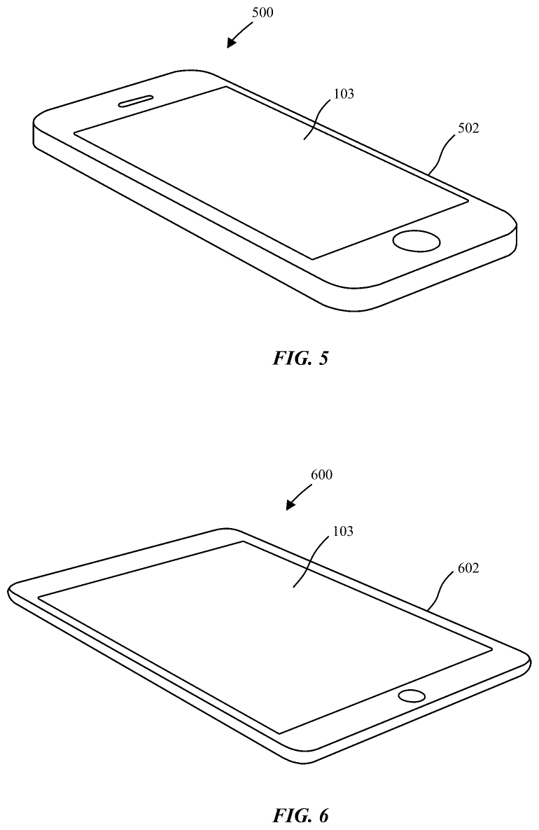

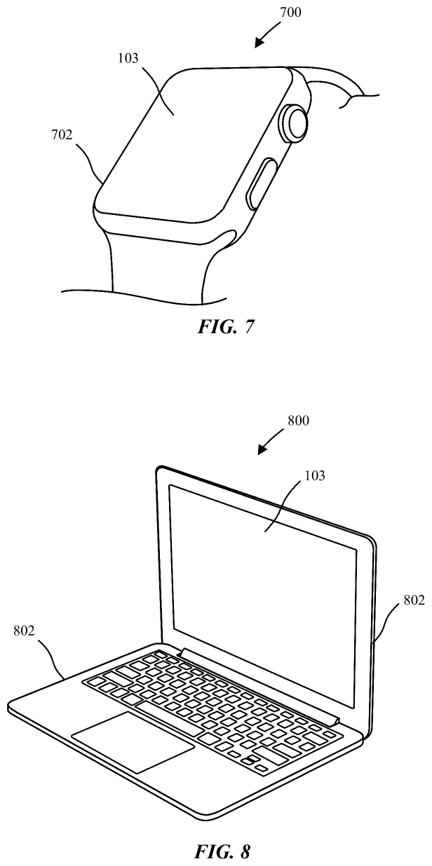

FIGS. 5-8 illustrate various portable electronic systems in which the various embodiments can be implemented. FIG. 5 illustrates an exemplary mobile telephone 500 that includes a display substrate 202 packaged in a housing 502. FIG. 6 illustrates an exemplary tablet computing device 600 that includes a display substrate 202 packaged in a housing 602. FIG. 7 illustrates an exemplary wearable device 700 that includes a display substrate 202 packaged in a housing 702. FIG. 8 illustrates an exemplary laptop computer 800 that includes a display substrate 202 packaged in a housing 802.

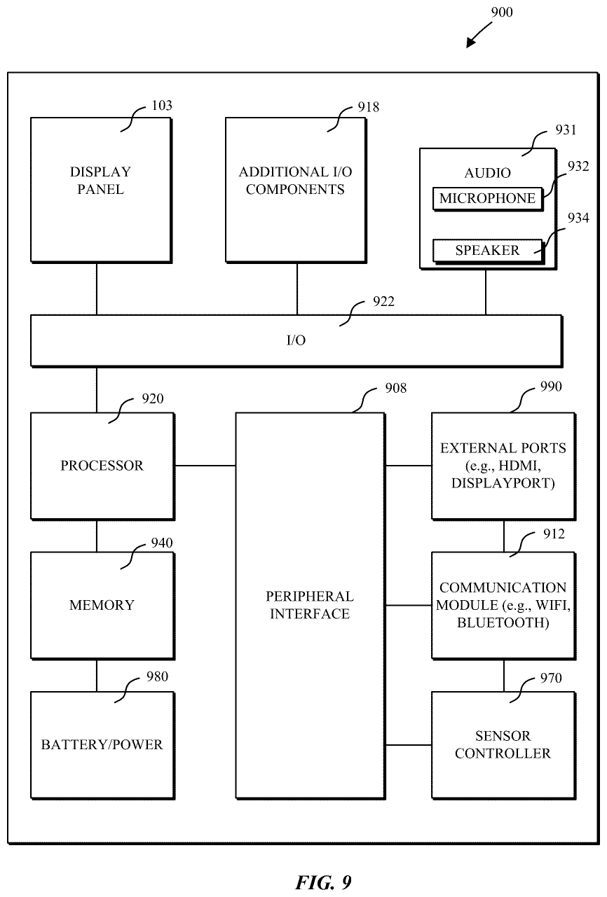

FIG. 9 illustrates a system diagram for an embodiment of a portable electronic device 900 including a display panel 103 described herein. The portable electronic device 900 includes a processor 920 and memory 940 for managing the system and executing instructions. The memory includes non-volatile memory, such as flash memory, and can additionally include volatile memory, such as static or dynamic random access memory (RAM). The memory 940 can additionally include a portion dedicated to read only memory (ROM) to store firmware and configuration utilities.

The system also includes a power module 980 (e.g., flexible batteries, wired or wireless charging circuits, etc.), a peripheral interface 908, and one or more external ports 990 (e.g., Universal Serial Bus (USB), HDMI, Display Port, and/or others). In one embodiment, the portable electronic device 900 includes a communication module 912 configured to interface with the one or more external ports 990. For example, the communication module 912 can include one or more transceivers functioning in accordance with IEEE standards, 3GPP standards, or other communication standards, 4G, 5G, etc. and configured to receive and transmit data via the one or more external ports 990. The communication module 912 can additionally include one or more WWAN transceivers configured to communicate with a wide area network including one or more cellular towers, or base stations to communicatively connect the portable electronic device 900 to additional devices or components. Further, the communication module 912 can include one or more WLAN and/or WPAN transceivers configured to connect the portable electronic device 900 to local area networks and/or personal area networks, such as a Bluetooth network.

The portable electronic device 900 can further include a sensor controller 970 to manage input from one or more sensors such as, for example, proximity sensors, ambient light sensors, or infrared transceivers. In one embodiment the system includes an audio module 931 including one or more speakers 934 for audio output and one or more microphones 932 for receiving audio. In embodiments, the speaker 934 and the microphone 932 can be piezoelectric components. The portable electronic device 900 further includes an input/output (I/O) controller 922, a display panel 103, and additional I/O components 918 (e.g., keys, buttons, lights, LEDs, cursor control devices, haptic devices, and others). The display panel 103 and the additional I/O components 918 may be considered to form portions of a user interface (e.g., portions of the portable electronic device 900 associated with presenting information to the user and/or receiving inputs from the user).

In utilizing the various aspects of the embodiments, it would become apparent to one skilled in the art that combinations or variations of the above embodiments are possible for forming a micro LED with multi-layer encapsulation layer. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. A micro LED structure comprising:
a micro diode including:
a top cladding layer with a first dopant type;
a bottom cladding layer with a second dopant type opposite the first dopant type;
a sidewall passivation layer spanning around sidewalls of the micro diode and at least partially underneath the micro diode, wherein the sidewall passivation layer forms an outline around the micro diode; and
a multi-layer encapsulation layer on the sidewall passivation layer, wherein the multi-layer encapsulation layer forms an outline along a portion of the sidewall passivation layer.

2. The micro LED structure of claim 1, further comprising an active layer between the top cladding layer and the bottom cladding layer.

3. The micro LED structure of claim 2, wherein the active layer comprises a plurality of quantum well layers.

4. The micro LED structure of claim 1, further comprising a transparent conductive oxide (TCO) layer underneath the bottom cladding layer, wherein the sidewall passivation layer is formed directly on an underside of the TCO layer.

5. The micro LED structure of claim 4, wherein the TCO layer comprises indium tin oxide (ITO).

6. The micro LED structure of claim 4, wherein the sidewall passivation layer comprises a metal oxide.

7. The micro LED structure of claim 6, wherein the sidewall passivation layer comprises aluminum oxide.

8. The micro LED structure of claim 6, wherein the multi-layer encapsulation layer comprises a first adhesion layer formed directly on the sidewall passivation layer and one or more barrier layers.

9. The micro LED structure of claim 8, wherein the first adhesion layer is a same composition as the sidewall passivation layer.

10. The micro LED structure of claim 9, wherein the one or more barrier layers comprises a hafnium oxide layer.

11. The micro LED structure of claim 10, wherein the one or more barrier layers comprises a plurality of hafnium oxide layers.

12. The micro LED structure of claim 8, wherein the one or more barrier layers includes alternating layers of a first group of barrier layers of a first metal oxide composition and a second group of barrier layers of a second metal oxide composition different from the first metal oxide composition.

13. The micro LED structure of claim 12, wherein the first metal oxide composition and the second metal oxide composition are each selected from the group consisting of zirconium oxide, tantalum oxide, hafnium oxide, and aluminum oxide.

14. The micro LED structure of claim 13, wherein:
the micro diode is designed to emit at a peak wavelength range; and
the one or more barrier layers form a distributed Bragg reflector (DBR) layer designed to be reflective of the peak wavelength range.

15. The micro LED structure of claim 6, further comprising:
a first opening in the sidewall passivation layer underneath the TCO layer; and
a mirror layer spanning a portion of the sidewall passivation layer and in direct contact with the TCO layer within the first opening in the sidewall passivation layer.

16. The micro LED structure of claim 15, further comprising:
a second opening in the multi-layer encapsulation layer underneath the mirror layer; and
a bonding layer spanning a portion of the multi-layer encapsulation layer and in direct contact with the mirror layer within the second opening in the multi-layer encapsulation layer.

17. An electronic device comprising:
a substrate;
a plurality of micro light emitting diodes (LEDs) mounted on the substrate; and
an insulation fill material laterally surrounding the plurality of micro LEDs;
wherein each micro LED comprises:
a micro diode including:
a top cladding layer with a first dopant type;
a bottom cladding layer with a second dopant type opposite the first dopant type;
a sidewall passivation layer spanning around sidewalls of the micro diode and at least partially underneath the micro diode, wherein the sidewall passivation layer forms an outline around the micro diode; and
a multi-layer encapsulation layer on the sidewall passivation layer, wherein the multi-layer encapsulation layer forms an outline along a portion of the sidewall passivation layer.

18. The electronic device of claim 17, wherein the insulation fill material comprises a polymer.

19. The electronic device of claim 18, further comprising a transparent conductive oxide (TCO) layer underneath the bottom cladding layer, wherein the sidewall passivation layer is formed directly on an underside of the TCO layer.

20. The electronic device of claim 19, wherein the multi-layer encapsulation layer comprises a first adhesion layer formed directly on the sidewall passivation layer and one or more barrier layers.
